(19) United States
(12) Patent Application Publication
(10) Pub. No.: US 2011/0024772 A1
(43) Pub. Date: Feb. 3, 2011

(54) ELECTRICAL CONNECTION FOR SEMICONDUCTOR STRUCTURES, METHOD FOR THE PRODUCTION THEREOF, AND USE OF SUCH A CONNECTION IN A LUMINOUS ELEMENT

(75) Inventor: Georg Diamantidis, Dernbach (DE)

Correspondence Address: LEMPIA BRAIDWOOD LLC, One North LaSalle Street, CHICAGO, IL, 60602, US

(73) Assignee: NOCTRON SOPARFI S.A., Bridel (LU)

(21) Appl. No.: 12/528,432

(22) PCT Filed: Sep. 12, 2007
(86) PCT No.: PCT/EP2007/007921

§ 371 Date: Oct. 22, 2010

(30) Foreign Application Priority Data
Feb. 23, 2007 (DE) 10 2007 009 351.0

(51) Int. Cl. H01L 33/00; H05K 1/09; H01R 43/00

(52) U.S. Cl. 257/88; 174/257; 29/825; 257/E33.055

(57) ABSTRACT

The invention relates to a method for electrically contacting an arrangement of a plurality of semiconductor structures comprising contact regions therefor and emitting electromagnetic radiation when a voltage is applied thereto. According to said method, a viscous, hardenable material is applied to the arrangement of a plurality of semiconductor structures and hardened to form a material web. The invention also relates to a luminous element comprising a plurality of semiconductor structures (12) which are interconnected by means of an electrical contacting element (34) and emit visible electromagnetic radiation when a voltage is applied thereto. The electrical contacting element (34) at least partially comprises at least one material web (34) obtained by hardening a material which is viscous in its basic state.

The invention relates to an electrical connection for semiconductor structures, to a method for the production thereof and to the use of such a connection in a light-emitting element.

Conventionally semiconductor structures used in light-emitting devices are made from an epi wafer, i.e. from a wafer cut from a semiconductor monocrystal. The semiconductor structures are built up on the epi wafer using photolithographic and/or dry etching methods. To form a light-emitting element, the semiconductor structures built up in this way are cut out of the wafer as individual LED chips and mounted as individual LED chips on a carrier substrate.

To produce an electrical connection, each LED chip has additionally to be bonded.

The bonding wires used for this purpose are extremely thin and delicate, such that the LED chips have to be encapsulated immediately after bonding, so as to protect them.

It is even more problematic if a plurality of individual semiconductor structures or LED chips, arranged in a specific geometry, have to be interconnected with one another, for example are to be connected in series or in parallel.

The object of the invention is to indicate an electrical connection and a method for the production thereof which ensure that a plurality of semiconductor structures may be reliably and compactly electrically contacted.

This object is achieved by a connection according to claim 1 or a method according to claim 10.

The invention thus makes it possible to bring about electrical contacting directly on a carrier substrate bearing a plurality of semiconductor structures, such that a plurality of semiconductor structures interconnected as desired may be cut out of the carrier substrate, which may even be the wafer itself, as a component handleable in one piece and thus form a light-emitting element without subsequent bonding.

Advantageous further developments of the invention constitute the subject matter of dependent claims.

By selecting the viscosity of a viscous curable material for the plastics film, the processability thereof may be conformed to the selected method of applying the material to the semiconductor structures.

By using a printing stencil to produce the conductor tracks, a precise connection diagram may be printed onto the arrangement of semiconductor structures. The printing stencil for conductor tracks may be a “microscreen contact stencil”.

Use of a material indicated in claim 13 is favourable with regard to the handleability thereof.

It is favourable for a sealing material to be applied to the semiconductor structure. The sealing material may again preferably be printed on using a printing stencil. The semiconductor structures are protected from external influences by the sealing material or the sealing layer. Furthermore, the risk of incorrect interconnection is also reduced.

According to a preferred use of the invention, a light-emitting element is obtained which may be produced more cost-effectively and reliably than such an element with interconnections formed by means of bonding wires. In this element the electrical contacting comprises at least partially flat tracks of electrically conductive material, and said element is distinguished, compared with a light-emitting element with electrical contacting by bonding wires, by greater mechanical stability and a greater load capability.

The carrier substrate may on the one hand be formed of wafer material itself. It is however also possible to use a separate substrate, such as for example a glass substrate or the like, to which individual semiconductor structures are applied.

The measure according to claim 31 on the one hand ensures that the light-emitting element distributes or outputs light uniformly and on the other hand ensures good heat dissipation.

The measure according to claim 32 consists in the possibility of producing radiation by means of optionally less expensive semiconductor structures, said radiation having a different spectrum from the radiation originally emitted by the semiconductor structures.

Exemplary embodiments of the invention are explained in greater detail below with reference to the attached drawings, in which:

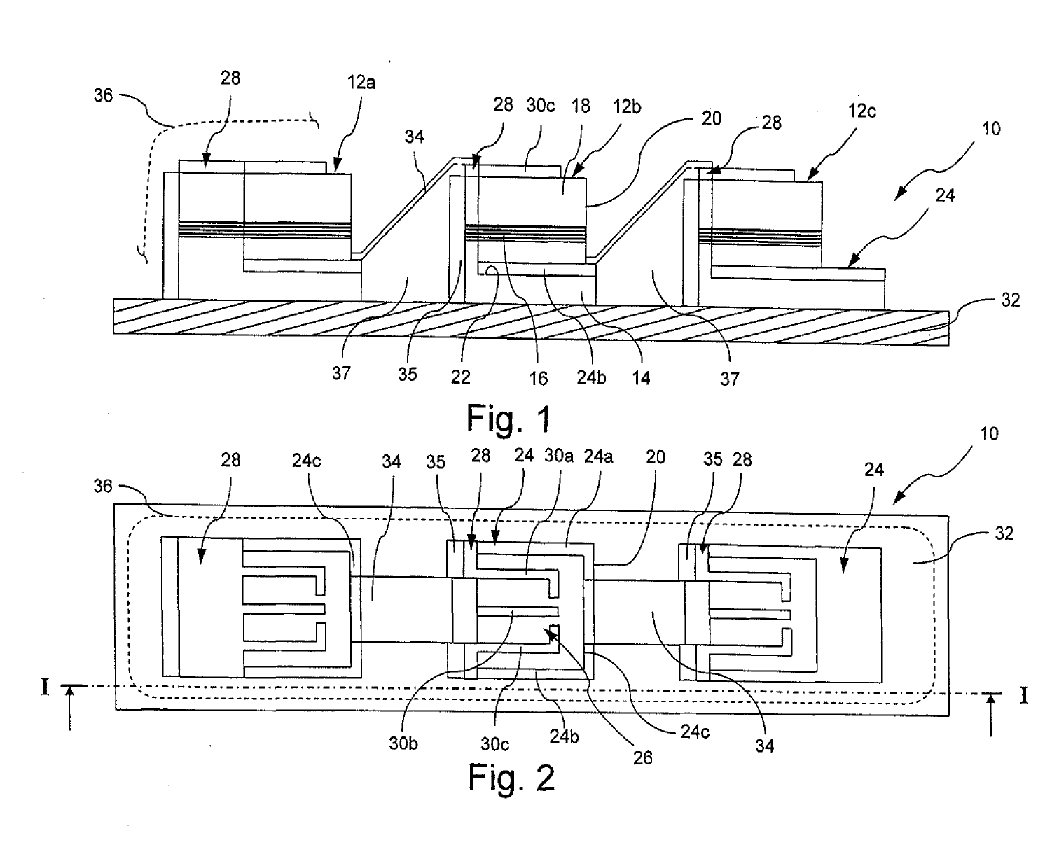

FIG. 1 shows a partial section through an LED element, in which three light-emitting chips are shown, cut along section line I-I of FIG. 2;

FIG. 2 is a plan view of the light-emitting element of FIG. 1;

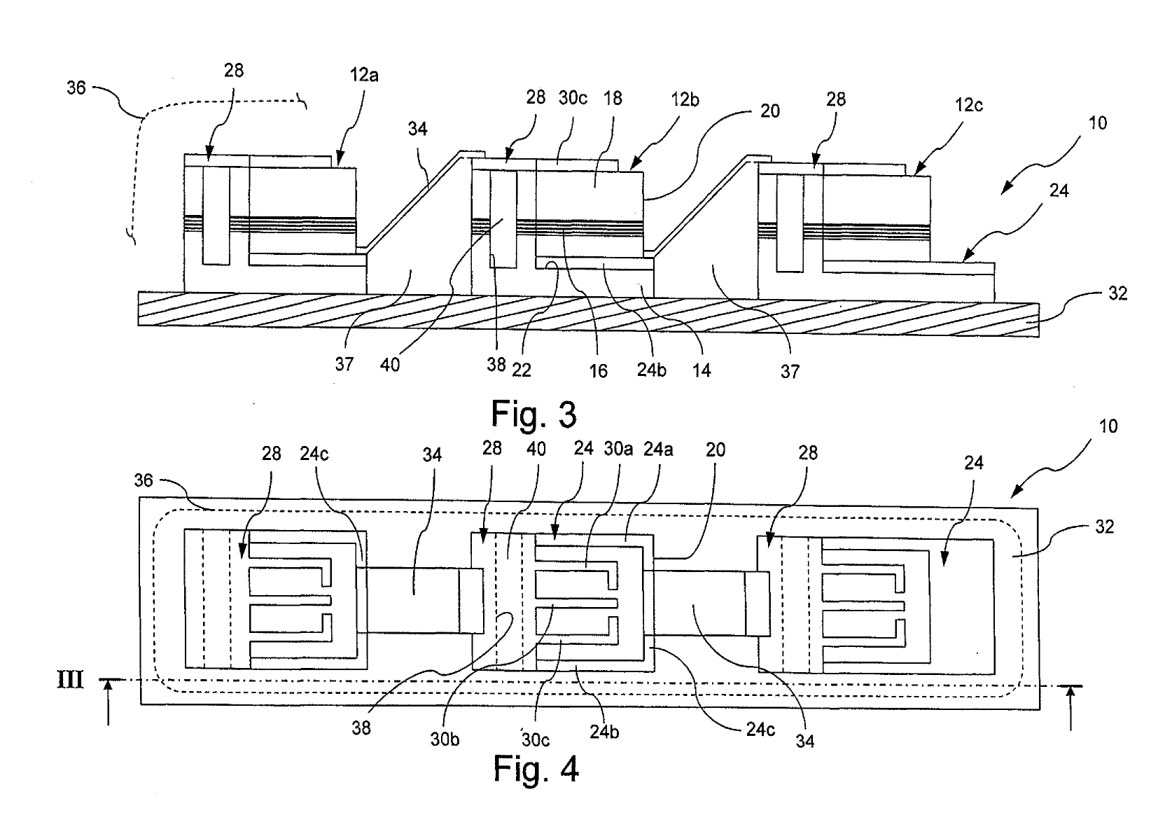

FIG. 3 shows a partial section through a modified light-emitting element along section line III-III of FIG. 4;

FIG. 4 is a plan view of the light-emitting element of FIG. 3;

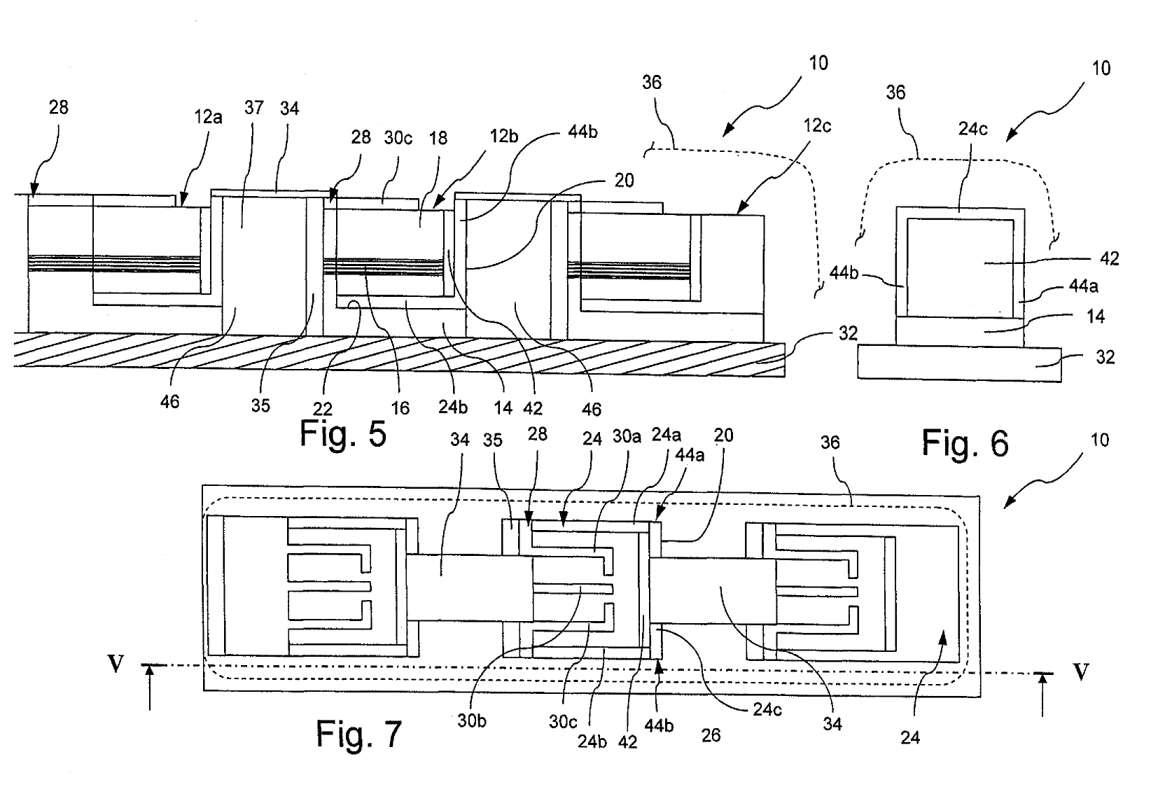

FIG. 5 shows a partial section through a further modified light-emitting element along section line V-V of FIG. 7;

FIG. 6 is an end view of the light-emitting element of FIG. 5;

FIG. 7 is a plan view of the light-emitting element of FIGS. 5 and 6;

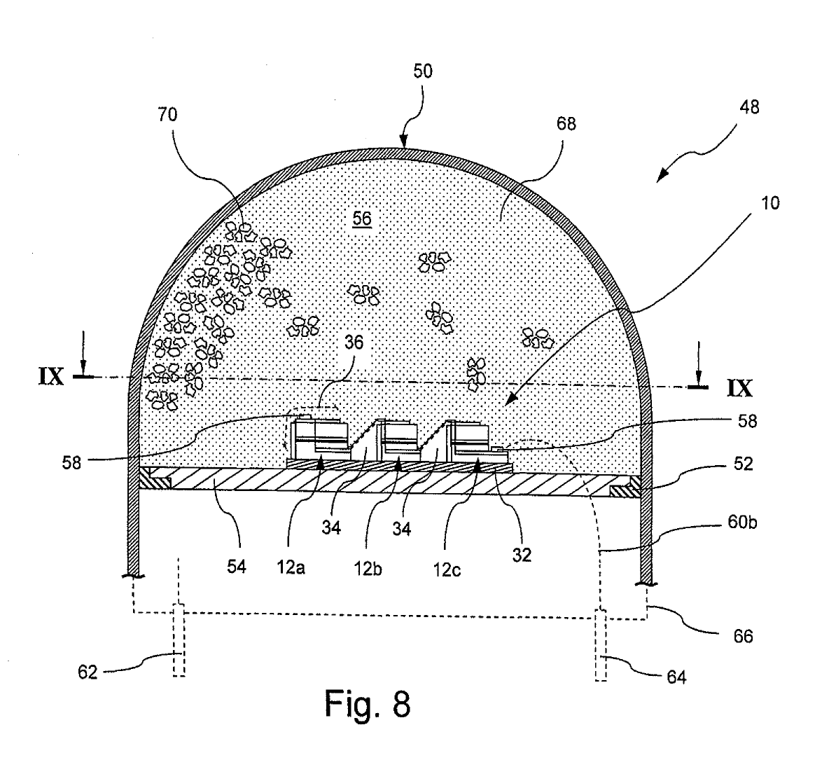

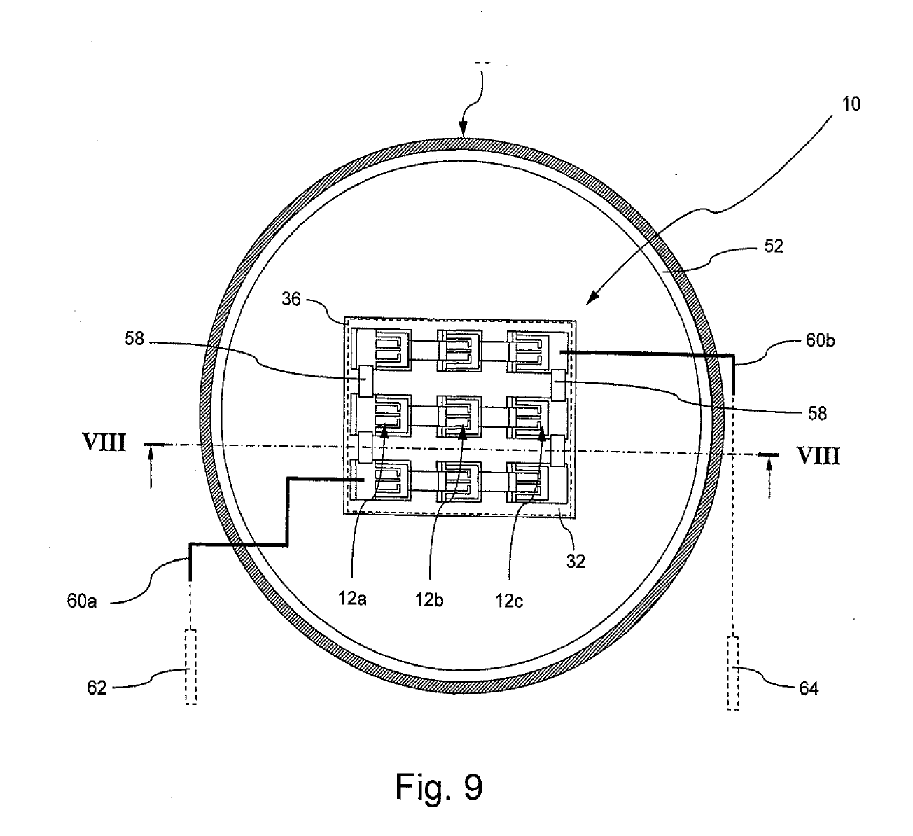

FIG. 8 shows a section through a light-emitting element with a further modified light-emitting chip arrangement along section line VIII-VIII of FIG. 9;

FIG. 9 shows a section through the light-emitting element of FIG. 8 along section line IX-IX therein;

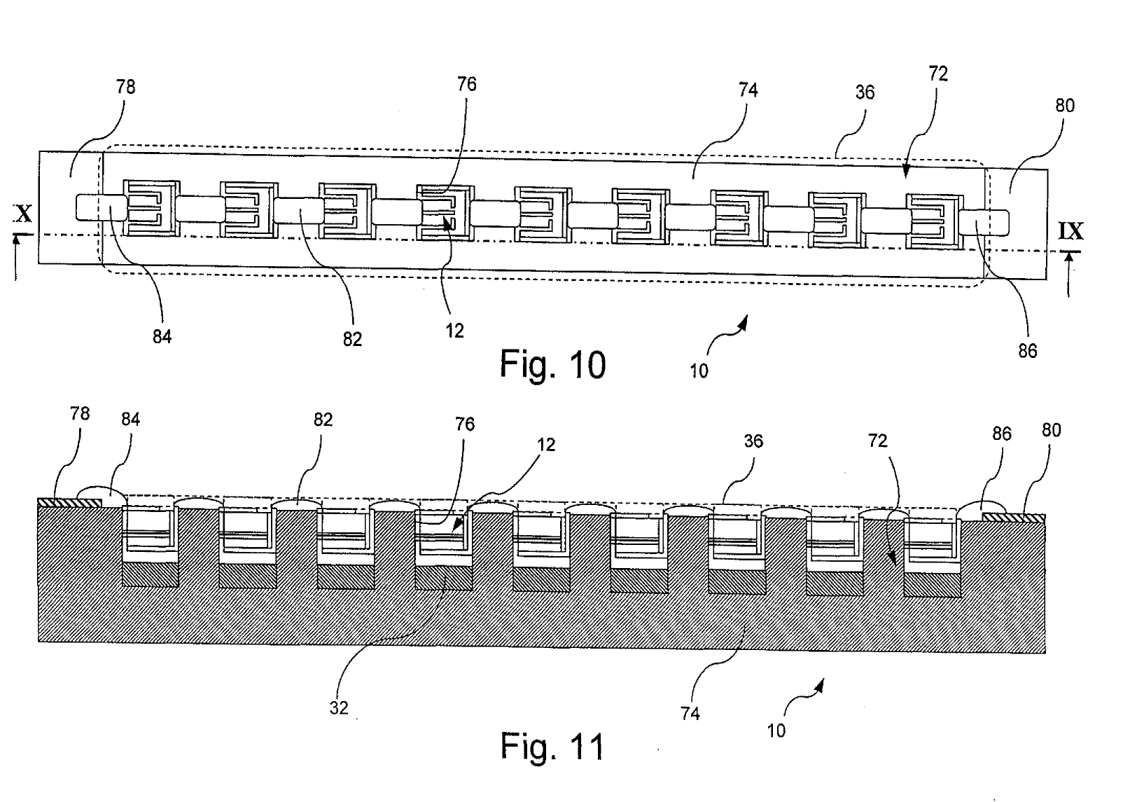

FIG. 10 is a plan view of another modified light-emitting element with a plurality of individual light-emitting chips;

FIG. 11 shows a section through the light-emitting element of FIG. 10 along section line XI-XI therein;

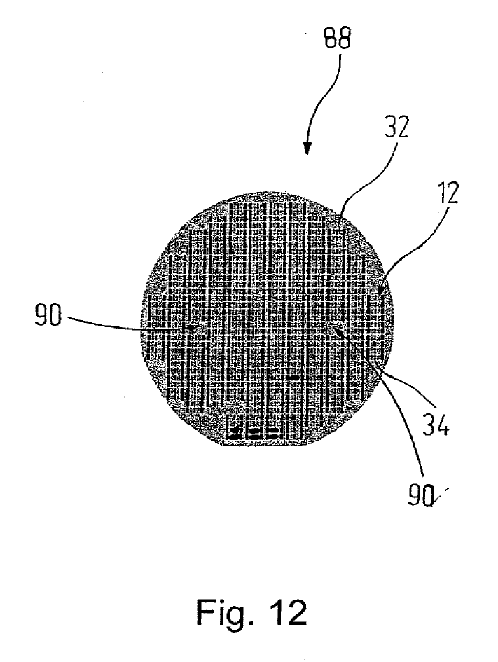

FIG. 12 is a plan view of a wafer with a plurality of light-emitting chip semiconductor structures connected together electrically, a number of semiconductor structures having already been cut out of the wafer;

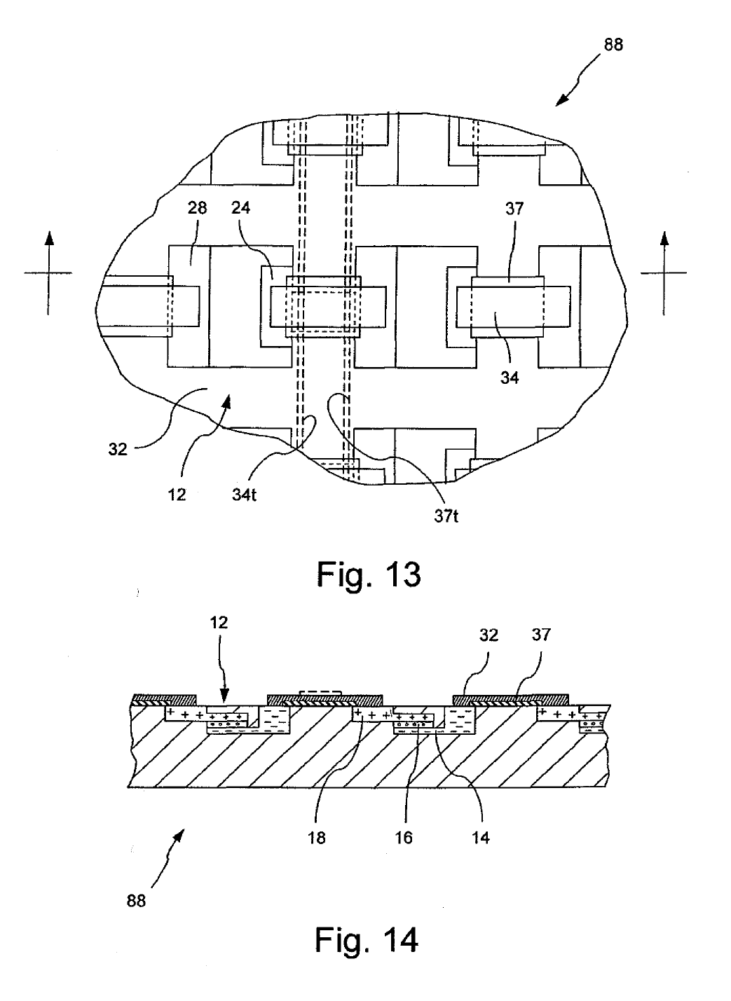

FIG. 13 is a plan view of a detail from a modified wafer with a plurality of electrically connected semiconductor structures in a larger scale than FIG. 12; and

FIG. 14 shows a longitudinal section through the wafer according to FIG. 13 along section line IVX-IVX therein.

In FIGS. 1 and 2 a light-emitting element, designated overall as 10, comprises three semiconductor structures 12a, 12b and 12c. Each of the semiconductor structures 12 is built up from three layers, this being explained below with reference just to the centrally arranged semiconductor structure 12b in FIG. 1 as an example.

The layer 14 at the bottom in FIG. 1 is an n-conducting layer, which consists for example of n-GaN or indeed of n-InGaN.

A middle layer 16 is an MQW layer. MQW is the abbreviation for “Multiple Quantum Well”. An MQW material has a superlattice, which comprises an electronic band structure modified in accordance with the superlattice structure and accordingly emits light at different wavelengths. Selection of the MQW layer makes it possible to influence the spectrum of the radiation emitted by the pn semiconductor structure 12.

A top layer 18 is made from a p-conducting III-V semiconductor material, for example from p-GaN.

Each semiconductor structure 12a, 12b and 12c comprises a step 20, which is U-shaped in plan view, whose horizontal step face 22 lies vertically below the MQW layer 16. In this way in the region of the step face 22 the n-conducting layer 14 projects laterally beyond the MQW layer 16 and the p-conducting layer 8.

The step face 22 is covered with a correspondingly U-shaped vapour-deposited conductor track 24 with two parallel conductor track legs 24a and 24b and a conductor track base 24c extending perpendicularly thereto (see FIG. 2). The conductor track 24 forms a contact zone to the n-conducting layer 14.

In order also to be able to contact the p-conducting layer 18, a conductor track 28 is vapour-deposited on the top thereof in a region 26 offset inwards from the U-shaped conductor track 24 when viewed in plan view, which conductor track 28 forms a contact zone to the p-conducting layer 18.

From the conductor track 28 three initially parallel conductor track legs 30a, 30b and 30c extend on the surface of the p-conducting layer 18 into the region 26 of the p-conducting layer 18. The free ends of the outer two conductor track legs 30a and 30c are each bent by 90° towards the middle conductor track leg 30b, as is clearly visible in FIG. 2.

The region 26 of the semiconductor structure 12 covers an area 280 μm×280 μm to 1800 μm×1800 μm. The height of the semiconductor structure 12 amounts to 180 μm to 400 μm.

The conductor track legs 24a, 24b and 24c are obtained by vapour deposition of a copper/gold alloy. Alternatively, silver or aluminium alloys may also be used. In the region of the conductor tracks 24c and 28 forming contact terminals, gold may be provided, which is doped for connection to a p-conducting layer or an n-conducting layer.

The three semiconductor structures 12a, 12b and 12c are borne by a carrier substrate 32. The carrier substrate 32 may be a sapphire glass, or corundum glass (Al₂O₃ glass). In the case of sapphire glass the carrier substrate 32 has a thickness of approx. 400 μm, but it may also have other thicknesses, which may for example lie between 5 μm and 600 μm.

Instead of sapphire glass a cheaper material in the form of a high-temperature-resistant glass such as for example Pyrex® glass may also be used for the carrier substrate 32.

Alternatively, the carrier substrate 32 may also be made of undoped wafer material, on which the semiconductor structures 12a, 12b and 12c are built up using per se known methods. In this case the semiconductor structures 12a, 12b and 12c are joined together in one piece. To ensure sufficient mechanical strength if the carrier substrate 32 is made of wafer material, said carrier substrate may optionally be borne by a base substrate, which may in turn be made for example from sapphire glass.

As is clear from FIGS. 1 and 2, the top contact terminal (conductor track 28) of the semiconductor structure 12a is larger in area than in the semiconductor structures 12b and 12c. In addition, the lower contact terminal formed by the conductor track leg 24c of the semiconductor structure 12c is larger in area than the corresponding contact terminal of the semiconductor structures 12a and 12b (see FIG. 2).

Thus, readily accessible terminal points are present, for connecting the light-emitting element 10 to a voltage source.

The semiconductor structures 12a, 12b and 12c are connected in series, to which end the conductor track leg 24c of the semiconductor structure 12a on the left in FIGS. 1 and 2 is connected electrically conductively with the conductor track 28 of the middle semiconductor structure 12b, of which the conductor track 24c is connected electrically conductively with the conductor track 28 of the semiconductor structure 12c on the right in FIGS. 1 and 2.

To this end, an electrical connection is provided in each case between the semiconductor structures 12a and 12b, which connection is formed in the exemplary embodiment according to FIGS. 1 and 2 of a ramp-shaped conductor track 34, which electrically conductively bridges the distance between two adjacent semiconductor structures 12. This is of the order of magnitude of 100 μm.

The ramp-shaped conductor track 34 takes the form of a material web of an electrically conductive material, which is obtained by curing a viscous, electrically conductive material. This will be looked at in more detail later on.

In a plastics base material (matrix) of the conductor track 34, fine copper or silver particle or a mixture thereof may for example be homogenously distributed. A two-component material, such as a two-component adhesive, is feasible as base material for the conductor track 34.

The semiconductor structures 12 comprise on their side opposite the step 20, on the left in FIGS. 1 and 2, an insulation layer 35, which prevents the conductor track 34 from contacting in each case on this side one of the layers 14, 16 or 18 of the semiconductor structures 12.

The insulation layer 35 may be made for example of undoped wafer material, which is left on a wafer or other carrier substrate when the semiconductor structures 12 are being built up.

In an alternative embodiment an insulator formed of a ramp-shaped material web is provided in each case between the semiconductor structures 12a and 12b or 12b and 12c, said insulator bearing reference numeral 37 in the Figures.

To this end, for example, an electrically insulating material may be applied between the corresponding semiconductor structures 12. A conductor track 34 may then be applied to the ramp-shaped insulator 37, for example by vapour deposition, said conductor track 34 consisting for example of the same material as has been described above in relation to the conductor track legs 24 and 30 or the conductor track 28. The electrical insulator 37 thus serves as it were as a support for the conductor track 34, which provides a smooth transition from the conductor track 24 of one semiconductor structure to the conductor track 28 of the adjacent semiconductor structure.

Those regions of the conductor track legs 24c of the semiconductor structures 12a and 12b and those regions of the conductor track 28 of the semiconductor structure 12b which are contacted by the ramp-shaped conductor track 34 or the insulator 37 with conductor track 34 constitute contact zones of the semiconductor structures 12. The larger-area conductor track 28 of the semiconductor structure 12a and the larger-area conductor track 24c of the semiconductor structure 12c form contact zones, specifically for connection to an external structure such as a printed circuit board or indeed another light-emitting element.

Apart from in these contact zones, the semiconductor structures 12a, 12b and 12c are coated with a transparent varnish 36, which is indicated in FIGS. 1 and 2 for clarity's sake merely by a broken line.

In a further modification, not specifically shown here, in which the ramp-shaped conductor track 34 of an electrically conductive material is provided, the semiconductor structures 12a, 12b and 12c do not only comprise an insulation layer 35 but rather are surrounded by a corresponding insulation layer, which, like the insulation layer 35, may be formed of undoped wafer material. In this case too the ramp-shaped conductor track 34 does not contact any of the layers 14, 16 and 18 of the semiconductor structures 12, but rather merely the left-behind undoped wafer material.

FIGS. 3 and 4 show an alternative exemplary embodiment of a light-emitting element 10, those components which correspond to components shown in FIGS. 1 and 2 bearing the same reference numerals. The light-emitting element 10 corresponds substantially to the light-emitting element 10 according to FIGS. 1 and 2.

However, in contrast, the semiconductor structures 12a, 12b and 12c of the light-emitting element 10 are not provided with an insulation layer 35, but rather in each case a through channel 38 is provided below the conductor track 28, which channel is filled with an insulating material 40. This also prevents undesired contact between the conductor track 34 and one of the layers 14, 16 or 18, here located on the inside, of the semiconductor structures 12.

FIGS. 5 and 7 show a modified light-emitting element 10, in which components which correspond to components shown in FIGS. 1 and 2 bear the same reference numerals. However, the conductor tracks of the semiconductor structures 12a, 12b and 12c comprise a different geometry from those of the light-emitting elements 10 according to FIGS. 1 to 4, which is explained by way of the semiconductor structure 12b in the middle in FIGS. 5 and 7.

As is clearly visible therein, the conductor track 24c for the n-conducting layer 14 is arranged in that plane in which are located the conductor track 28 and the conductor track legs 30a, 30b and 30c for the p-conducting layer 18.

To this end the semiconductor structure 12b is provided on the end face of the step 20 directed towards the conductor face 24c with an insulation layer 42 which covers said end face. Two conductor tracks 44a, 44b, which laterally flank the insulation layer 42, connect the conductor track base 24c with the conductor track legs 24a and 24b.

In this way, instead of the ramp-shaped conductor track 34 or of the ramp-shaped insulator 37 with the conductor track 34, a cuboid insulator 37 may be provided, whose top extends at a uniform distance from the substrate 32 and bears the now horizontal connecting conductor track 32.

Accordingly, an insulator 37 with a vapour-deposited conductor track may alternatively be provided here, as explained above in relation to the ramp-shaped insulator 37 with conductor track 34.

The light-emitting elements 10 and in particular electrical contacting thereof by the conductor track 34 are obtained as follows:

The starting point is an arrangement of a plurality of semiconductor structures 12. Such an arrangement may take the form, for example, of semiconductor structures 12 which have been built up in a specific arrangement on a carrier material by means of photolithographic and/or dry-etching methods.

The carrier material for the semiconductor structures 12 may take the form for example, as mentioned above, either of the wafer material itself or a layer of sapphire glass or another substrate material.

The arrangement and design of the semiconductor structures 12 on the carrier substrate is known, whereby the respective positions and dimensions of the above-mentioned contact zones for electrical contacting of the semiconductor structures 12 with one another are also known. Furthermore, the profiles of desired conductor tracks, which are intended to connect specific contact zones of the semiconductor structures electrically together, also follow therefrom.

A printing stencil for sealing is then produced, which, when it is positioned over the side of the semiconductor structures with the contact zones, covers the contact zones and the course of the desired conductor tracks and thus the circuit diagram of the semiconductor structures 12. A material for sealing may comprise a transparent curable organic plastics material, for example an acrylate or epoxy resin.

A printing stencil for conductor tracks is correspondingly produced, which, when it is positioned over the side of the semiconductor structures with the contact zones, covers all regions of the arrangement of the semiconductor structures 12, apart however from the contact zones and the course of the desired conductor tracks and thus the circuit diagram of the semiconductor structures 12.

The printing stencil for conductor tracks thus forms a negative of the printing stencil for sealing. Such a printing stencil for conductor tracks may likewise consist for example of highly viscous acrylate or epoxy resin, which contains a correspondingly large quantity of fine electrically conductive metal particles.

In the screen printing method first of all the printing stencil for sealing is appropriately positioned, and a sealing coat is printed therewith onto the arrangement of the semiconductor structures 12. As a result, the sealing coat then covers the entire wafer, apart from those regions which are needed for electrical contacting of the semiconductor structures 12.

The sealing coat is then cured to yield a sealing layer. Curing is understood to mean any processes with which a cohesive dimensionally stable layer is formed from a viscous, printable material, which layer is however still elastic and bendable depending on the plastics material used. This may be achieved by drying with or without targeted exposure to heat, by chemical reaction, by electromagnetic radiation or particle radiation.

Once the sealing coat has cured to yield a sealing layer, the printing stencil for the conductor tracks is appropriately positioned and a viscous, curable conductor track material is printed onto the arrangement of semiconductor structures 12, as has already been explained above. This material is then cured again as above to yield a cohesive material film.

The material films obtained after the printing process and curing form conductor tracks 34, which jointly effect electrical contacting of the arrangement of semiconductor structures 12. As a result of the circuit diagram predetermined by means of the printing stencil for conductor tracks, it is established which semiconductor structures 12 are interconnected on the carrier material and whether they are connected in parallel or in series.

Similar methods are carried out to produce the ramp-shaped insulators 37 or the cuboid insulators 37.

In this case, after the printing process and after curing a plurality of insulators or supports 37 are present, to which the conductor tracks 34 are applied in a subsequent step.

When proceeding as described above to produce the electrical connections to the semiconductor structures, care must naturally be taken to ensure that the printing stencil for sealing material or insulation material covers the contact zones of the semiconductor structures 12, while these regions are left exposed by the printing stencil for connecting conductor production.

Alternatively, the connecting conductor tracks 34 may also be obtained by vapour deposition.

The printing templates for sealing and the printing stencil for conductor tracks are worked for instance to an accuracy of +/−1.0 μm.

Optionally, sealing of the arrangement of semiconductor structures with a sealing coat may be omitted and the semiconductor structures may be electrically contacted without prior sealing. The sealing layer may also be applied as a final layer.

As a result of the above-described procedure, all the semiconductor structures 12 on the carrier substrate may be interconnected. However in this way it is also possible in each case to interconnect a plurality of groups of semiconductor structures 12, which in each case comprise a predetermined number of semiconductor structures 12, electrically on the carrier material 32. These groups may then be cut, ready interconnected, from the overall wafer using laser cutting methods for example.

An example of possible use for an arrangement of preconnected semiconductor structures 12 obtained in one piece in this way is described below.

FIGS. 8 and 9 show sections through a light-emitting device 48, which comprises a cylindrical housing 50 of transparent glass or plastics. On the cylindrical internal wall of the housing 50 there is arranged a retaining ring 52, which in turn bears a base plate 54. The housing 50, the retaining ring 52 and the base plate 54 define an internal chamber 56.

In said chamber a light-emitting element 10 is seated on the base plate 54, in which nine semiconductor structures 12 are arranged in a 3×3 matrix on the carrier substrate 32. As is clear from FIG. 9, in the 3×3 matrix of semiconductor structures 12 three series-connected chains with in each case three semiconductor structures 12a, 12b and 12c are connected in parallel.

Series connection of the in each case three semiconductor structures 12a, 12b and 12c proceeds as shown in FIGS. 1 to 4 by means of the ramp-shaped conductor tracks 34. The semiconductor structures 12a or 12c arranged at the start or end of a chain are in each case connected in parallel by way of conductor tracks 58. The conductor tracks 58 correspond to the conductor tracks 34.

The light-emitting element 10 could be cut out of the original wafer as a one-piece component, which, apart from the terminals for connection to a voltage source, was already interconnected.

The light-emitting element 10 is supplied with power via a first supply line 60a and a second supply line 60b.

To this end, the supply lines 60a and 60b are connected in conventional manner to connection pins 62 or 64, which project out of a fastening base 66 of the light-emitting device 48, which is indicated only schematically in FIGS. 8 and 9.

The internal chamber 56 of the housing 50 is closed by a hemispherical housing portion. In the internal space 56 of the housing 50 a liquid is provided in the form of silicone oil 68, which is indicated as dots.

The silicone oil on the one hand conducts the light emitted by the semiconductor structures 12 and on the other hand dissipates heat produced by the semiconductor structures 12 to the outside, in particular to the walls of the housing 50.

The semiconductor structures 12 of p-GaN/n-InGaN emit ultraviolet light and blue light in a wavelength range of 420 nm to 480 nm when a voltage is applied. To generate white light with the semiconductor structures 12, different luminescent material particles 70 are distributed homogenously in the silicone oil 68. Such luminescent material particles consist of transparent solid materials comprising colour centres and absorb primary radiation impinging thereon, whereby they emit secondary radiation with a different (longer) wavelength. If the luminescent material particles or luminescent particle mixtures are suitably selected, the radiation emitted by the semiconductor structures 12 may thus be converted into radiation with a different spectrum, in particular white light.

FIGS. 10 and 11 show a modified luminescent device 72. In this a substrate 74 of glass is provided, in which recesses 76 are provided at regular intervals in a row.

The recesses 76 in each case contain one semiconductor structure 12, which is cut out of a wafer as an individual semiconductor structure 12. This means that here a semiconductor structure 12 is in each case seated on one carrier substrate 32, the area of which corresponds to that of the semiconductor structure 12 seated thereon.

The recesses 76 should be dimensioned such that each semiconductor structure 12 with the substrate 32 bearing it protrudes a little beyond the surface of the glass substrate 74.

The semiconductor structures in this case are semiconductor structures corresponding to the semiconductor structures 12 shown in FIGS. 5 to 7, with contact zones 24c and 28 arranged at the same level. The semiconductor structures 12 shown in FIGS. 1 to 4 may however likewise be used. Insulation layers 35 are not provided here, however.

For the above-described method of electrically contacting the semiconductor structures 12, use is not made of a wafer as an arrangement of a plurality of semiconductor structures 12 but rather the glass substrate 72 is used with individual semiconductor structures 12 inserted therein. At the ends of the glass substrate 74 vapour-deposited contact surfaces 78 or 80 are provided, which may be connected to the semiconductor structures 12 in a method step using a corresponding printing stencil for conductor tracks.

As a result of the electrical contacting, the semiconductor structures 12 of the light-emitting element 72 are here series-connected, the electrical contacting between two adjacent semiconductor structures 12 being brought about by a conductor track 82 which consists of a material as explained above with reference to the ramp-shaped conductor track 34. Here too there is a possibility of laying a conductor track 34 over an insulator 37.

Parallel connection of the semiconductor structures 12 is also possible in this way.

In the luminescent device 72 too, a transparent varnish 36 indicated as a broken line is provided, which does not however enclose the semiconductor structures 12, but rather merely covers the free surfaces thereof apart from the contact zones to be connected.

The contact face 78 on the glass substrate 74 is connected to the conductor track 28 of the semiconductor structure 12 adjacent thereto via a conductor track 84.

Likewise, the contact face 80 is connected to the conductor track 24 of the semiconductor structure 12 adjacent thereto via a conductor track 86.

Instead of the glass substrate 74, a substrate 74 of acrylic sheet may also be used.

The substrate 74 has light-conducting properties, so producing a batten luminaire.

In this structure semiconductor structures 12 may be used which are of identical construction but, depending on production, have different luminous intensities. Due to homogeneous distribution by the substrate 74 of the light emitted by the semiconductor structures, homogeneous light emission takes place, so making it possible to dispense with expensive sorting and classification of the individual light-emitting chips after production on the basis of their different luminous powers.

In the case of a substrate 74 of glass or acrylic sheet, luminous devices 5 mm to 30 mm wide and 2 cm to 50 cm long may be readily produced, with a thickness of 0.5 mm to 5 mm.

As a substrate 74 a flexible plastics material may also be used, wherein the substrate 74 may take the form of a film. In this case, conductor tracks of copper or metal particle plastics coating which is flexible after curing may be applied to the flexible substrate 74, wherein electrical contacting of these conductor tracks with the semiconductor structures 12 proceeds using the above-explained method.

When using a flexible film as a substrate 74, several metres of a tape for example 1 cm wide and only 0.1 mm to 0.2 mm thick may be produced, which is provided with copper conductive tracks. To this end, individual semiconductor structures 12 are adhesively bonded onto the film and thereafter electrically contacted as explained above.

With such a tape, 10,000 to 100,000 light-emitting chips may be connected in series or parallel, wherein the “endless” tape may be cut into pieces of any desired length depending on requirements. In order to form a light-emitting element from a cut-out tape portion, all that is necessary is to provide the corresponding contact zones of the in each case external semiconductor structures 12 with terminals for a voltage source.

FIG. 12 shows a wafer 88 consisting of a carrier substrate 32 and a plurality of semiconductor structures 12 built up thereon. Of these, in each case two semiconductor structures 12 have been connected together electrically by means of the above-described method on the carrier substrate 32.

A number of semiconductor structures 12 arranged in a 2×2 matrix have already been cut out of the wafer 88 as a unit, which is clear from the gaps 90 in the arrangement of semiconductor structures 12.

A connecting conductor track 34 is visible in each case as a black line between two semiconductor structures 12 which are connected together electrically.

In the exemplary embodiment according to FIGS. 13 and 14, functionally identical elements, which have already been described with reference to the preceding Figures, are again provided with the same reference numerals and do not need to be described again in detail.

The main difference from the above-described Figures lies in the fact that the semiconductor structures are produced by diffusing in the dopants, such that the finished wafer has a flat surface. This means that the conductor tracks 24 and 28 also lie in a common plane and the conductor tracks 34 may readily extend parallel to the wafer surface. Only at the ends of the insulating layer 37 located therebelow are small steps formed, which may, however, readily be covered by screen printing.

For many semiconductor structures, which have an oxide layer on the wafer surface as a result of the production process, it is also possible to dispense with an insulating layer applied separately by screen printing, such that the conductor tracks 34 may be applied in a completely step-free manner.

As has already been described above, however, the profiles shown in FIGS. 1 to 12 of the semiconductor structures are greatly exaggerated in the direction perpendicular to the plane thereof, such that only very small steps are actually obtained, over which conductor tracks produced by screen printing may extend without the risk of sticking together.

As shown in broken lines in FIGS. 13 and 14, mutually adjacent rows of semiconductor structures may also be connected by the conductor tracks 34 provided at greater spacings of for example 3, 6 or 12 rows transverse conductor tracks 34t and the wafer may then be cut in the middle of the conductor tracks 34t. Units with rows of in each case for example 3, 6, or 12 series-connected semiconductor structures are then obtained. After separation in the direction parallel to the conductor tracks 34, ready-connected matrices with for example 3×1, 3×2, 3×3, etc. or 6×1, 6×2, 6×3, etc. or 12×1, 12×2, 12×3, etc. light-emitting semiconductor structures 12 are then obtained, for which it remains only to produce the terminals to live conductors.

Below the transversely extending conductor tracks 34t, in the case of inadequate electrical insulation of the semiconductor base material of the wafer, insulating layers 37t interrupted at the intersection points with the conductor tracks 34 may be provided, as likewise indicated with broken lines.

To apply the light-emitting matrices singulated in this way to a printed circuit board in mass production, it is likewise possible to use conductor tracks produced by screen printing, as described above for the connection of semiconductor structures 12. These connecting conductors then extend from the conductor tracks 34t to terminal conductor tracks of the printed circuit boards.

1. An electrical connection between a semiconductor structure and another structure, having a first terminal, which belongs to the semiconductor structure, and a second terminal, which belongs to the other structure, and having a connecting track of electrically conductive material, which extends from the first terminal to the second terminal,
wherein the first terminal and the second terminal take the form of flat contact zones and the connecting track is made of an electrically conductive plastics material film, which covers the two contact zones at least partially in a bonded manner.

2. A connection to claim 1,
wherein the contact zones comprise an area of at least 2 mm².

3. A connection according to claim 1,
wherein the plastics material film has a thickness of about 20 μm to about 200 μm.

4. A connection according to claim 1,
wherein the plastics material film comprises a filling of fine electrically conductive particles, which is incorporated into a plastics matrix.

5. A connection according to claim 4,
wherein the particles have a size of 10 μm to 100 μm.

6. A connection according to claim 4,
wherein the plastics matrix is electrically conductive.

7. A connection according to claim 1,
wherein the plastics material film is elastic.

8. A connection according to claim 1,
wherein the plastics material film exhibits at least one of the following properties: elasticity, plasticity, resistance to low temperatures down to −40° C., resistance to high temperatures up to 200° C.

9. A connection according to claim 1,
wherein the plastics material film comprises at least one material from the following group: natural and synthetic elastomers, epoxy resins, acrylates, urethanes.

10. A connection according claim 1,
wherein an insulating support is provided between the terminals, the top of which forms a recess-free, preferably smooth connection between the terminals.

11. A method of producing an electrical connection between at least one contact zone of one semiconductor structure and at least one contact zone of at least one other structure, the semiconductor structure preferably being such a structure which emits electromagnetic radiation when voltage is applied thereto,
the method compromising the following steps:
a) arranging the semiconductor structure and the other structure in a predetermined fixed spatial relationship to one another;
b) applying a viscous, pasty or pulverulent connector track material to a conductor track region, which at least partially overlaps the contact zones of the semiconductor structure and other structure, the conductor track being electrically conductive or being capable of bring made electrically conductive by subsequent treatment; and
c) subsequent treatment of the conductor track material applied to the arrangement of a plurality of semiconductor structures to form a cohesive conducting material web.

12. A method according to claim 11,
wherein the conductor track material comprises a curable material and the subsequent treatment is curing and/or the conductor track material comprises a fusible material and the subsequent treatment is heat treatment.

13. A method according to claim 12,
wherein the viscous curable material used is a two-component adhesive.

14. A method according to claim 12,
wherein the conductor track material comprises fine particles of a metal with good electrical conductivity and dispersed homogeneously in the curable material.

15. A method according to claim 12,
wherein the viscous curable material is selected from the following group: epoxy resins, acrylates, urethanes.

16. A method according to claim 11,
wherein, prior to method step b), a base layer of electrically insulating, viscous, pasty or pulverulent base layer material is applied to the semiconductor structure and/or the other structure in a region comprising at least part of a conductor track zone, which base material may be converted by subsequent treatment into a cohesive layer.

17. A method according to claim 16,
wherein the base layer material comprises a curable material and the subsequent treatment is curing and/or the base layer material comprises a fusible material and the subsequent treatment is heat treatment.

18. A method according to claim 16,
wherein subsequent treatment of the applied base layer proceeds before application of the conductor track material.

19. A method according to claim 11,
wherein, prior to the performance of step b) or after step b) or after step c), a viscous, pasty or pulverulent sealing material, which may be converted by subsequent treatment into a cohesive layer, is applied to the arrangement of semiconductor structures, the contact zones being left free.

20. A method according to claim 19,
wherein the sealing material comprises a curable material and the subsequent treatment is curing and/or the sealing material comprises a fusible material and the subsequent treatment is heat treatment.

21. A method according to claim 20,
wherein the sealing material takes the form of a varnish.

22. A method according to claim 19,
wherein the sealing material is transparent when cured.

23. A method according to claim 11,
wherein application of the conductor track material and/or of a base layer material and/or of a sealing material proceeds by means of at least one printing stencil or one printing form.

24. A method according to claim 11,
wherein one of the other structures is a carrier board and the semiconductor structures are arranged thereon in predetermined positions.

25. A method according to claim 11,
wherein one of the other structures is another semiconductor structure and the semiconductor structures are arranged on a carrier board in predetermined positions.

26. A method according to claim 25,
wherein the carrier board, prior to the performance of step b), is provided in regions located between contact zones of different semiconductor structures with insulating supports.

27. A method according to claim 11,
wherein method steps b) and c) are performed jointly on the wafer for the semiconductor structures lying thereon and wherein singulation of semiconductor structures or of groups of semiconductor structures from the wafer proceeds after step b).

28. A light-emitting element having a plurality of light-emitting semiconductor structures, which comprise at least one terminal zone and are arranged on a carrier substrate,
wherein a connection according to claim 1 is used for electrical connection of a semiconductor structure to the carrier substrate or another semiconductor structure.

29. A light-emitting element according to claim 28,
wherein on opposing sides, the semiconductor structures each have a first terminal zone for the supply of current and a second terminal zone for the removal of current.

30. A light-emitting according to claim 29,
wherein the semiconductor structures are connected extensively to the carrier substrate.

31. A light-emitting element according to claim 29,
wherein the carrier substrate comprises a glass material or a crystal material.

32. A light-emitting element according to claim 31,
wherein the carrier substrate comprises an Al₂O₃ material.

33. A light-emitting element according to claim 28,
wherein the semiconductor structures are arranged in an internal chamber of the light-emitting element, the internal chamber being filled with a heat-conducting insulating liquid.

34. A light-emitting element according to claim 28,
wherein the semiconductor structures are surrounded at least in places by substantially uniformly distributed luminescent material particles, which absorb radiation emitted by the semiconductor structures and convert it at least in part into complementary radiation.

35. A light-emitting element according to claim 34, wherein the semiconductor structures are arranged in an internal chamber of the light-emitting element, the internal chamber being filled with a heat-conducting insulating liquid,
and wherein the luminescent material particles are dispersed in the liquid.

36. A light-emitting element according to claim 28,
wherein terminal zones at the edges of a semiconductor structure or a group of semiconductor structures are larger than the terminal zones connected by an internal connection.

37. A connection according to claim 2, wherein the contact zones comprise an area of 3 to 10 mm².

38. A connection according to claim 1, wherein the plastics film material has a thickness of about 40 μm to about 100 μm.

39. A connection according to claim 4, wherein particles have a size of 20 μm to 50 μm.

40. A method according to claim 14, wherein the fine particles comprise gold, copper and/or silver particles.

41. A method according to claim 27, wherein the step of singulation proceeds after step c).

42. A light-emitting element according to claim 28, wherein the heat-conducting insulating liquid is a silicone oil.
